(19) United States
(12) Patent Application Publication
(10) Pub. No.: US 2012/0200317 A1
(43) Pub. Date: Aug. 9, 2012

(54) FEEDFORWARD/FEEDBACK CONTROL SYSTEM FOR INDUSTRIAL WATER SYSTEMS

(76) Inventors: John RICHARDSON, Hanover, VA (US); Ron Woods, Henrico, VA (US)

(21) Appl. No.: 13/207,412

(22) Filed: Aug. 10, 2011

Related U.S. Application Data
(60) Provisional application No. 61/372,453, filed on Aug. 10, 2010.

(51) Int. Cl. H03K 5/00

(52) U.S. Cl. 327/1

(57) ABSTRACT

A control system is disclosed for monitoring and controlling an industrial water system comprising (a) obtaining a priori knowledge about the correlation between water and treatment chemistry and equipment health; (b) pre-defining a set of operating regions of more than one feed-water or system water variable and at least one chemical treatment variable, where, based on (a) above, corrosion, scaling and fouling are inhibited; (c) adjusting the at least one chemical treatment variable according to the more than one feed water or system water variable, such that based on (a), corrosion, scaling and fouling are inhibited.

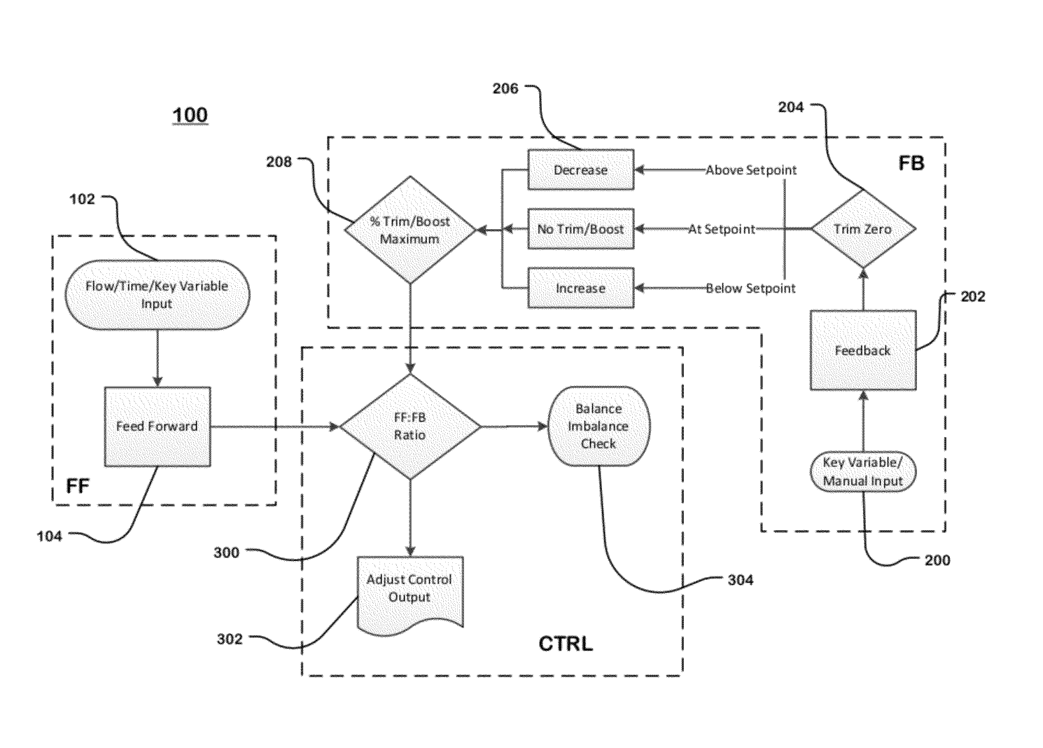

### PRIORITY STATEMENT

This application claims priority from U.S. Provisional Patent Appl. No. 61/372,453, which was filed on Aug. 10, 2010, the entire contents of which are hereby incorporated by reference.

### FIELD OF THE INVENTION

The field of the invention relates to systems for controlling industrial water systems using both feedforward and feedback data in light of both real time and historical data in order to improve the performance of water treatment packages for inhibiting corrosion/scaling/fouling and/or for dispersing particles while reducing the water, treatment chemicals and maintenance resources required to maintain the industrial water system. In particular the disclosed system provides real time control for industrial water systems including, for example, cooling water systems, boiler systems, water reclamation systems and water purification systems, while reducing maintenance and improving uptime performance.

### BACKGROUND OF THE INVENTION

Adequate supplies of water are essential to the development and operation of many industrial processes. Enormous quantities of water can be required in manufacturing processes including, for example, cooling products and/or equipment, feeding boilers, feeding evaporators and/or for providing sanitary and potable water supplies. The corrosiveness of water can pose a major threat to the wetted surfaces of industrial equipment resulting from the slow dissolution of metals into the water that can result in structural failure of process equipment. Conversely, the deposition of mineral scale on heat transfer surfaces from minerals precipitating from the circulating water and/or reacting with the metal(s) of the wetted surface reduces heat transfer efficiency, reduces flow channel diameter and increases maintenance requirements. Accordingly, controlling corrosion and scale is a major focus of modern water treatment technology.

Typical industrial water systems can be subject to wide variations resulting from environmental conditions including, for example, temperature, humidity and rainfall. While some characteristics vary with the changing seasons, depending on the location of the facility and the primary water source, variation in other characteristics can change abruptly and dramatically. In some instances, a significant portion of the total contaminant(s) within an industrial water system enters the system during a relatively brief time frame during which the contaminant levels are unusually high. These occurrences are sometimes referred to as “upset” conditions and are characterized by contaminant levels that may be several times greater than their typical or average levels. While typically brief, these upset events may continue for extended periods of time including, for example, under drought conditions that degrade the quality of river water being used as a makeup water source.

The source and severity of the upset condition will be significant factor in defining a response for maintaining control over the performance of the industrial water system and the treatment package(s) utilized within the industrial water system. Control strategies can include, for example, feed water feedforward control; system water feedforward control; treatment chemical feedback control or performance feedback control. As will be appreciated, the feedforward control strategies are more proactive but require prior knowledge regarding the relationship between the detected changes in the feed water and/or system water, the treatment package(s) available and the target circulating water composition that is expected to reduce or eliminate corrosion and scale on the wetted surfaces. The feedback control strategies, on the other hand, are based on direct performance measurements from various points within the industrial water system and/or the response expected from various feed rates of the available treatment package(s) into the industrial water system. Although feedback control strategies may be more easily implemented in those instances in which information regarding the correlation between water composition, treatment chemistry, corrosion and scale, because these control strategies are reactive, corrosion, scaling and fouling may occur before control is re-established within the industrial water system.

Under conventional practice, for example, calcium within the industrial water system is addressed using a treatment package including an inorganic orthophosphate in combination with one or more water soluble polymers for forming a protective film on the wetted surfaces in order to suppress corrosion. As will be appreciated, the concentration of the polymer(s) is an important factor in reducing formation of calcium phosphate (as well as calcium sulfate and calcium carbonate) crystals and avoiding scale comprising calcium compounds deposited on the wetted surface. A number of U.S. patents address various aspects of these polymers, their activity within an industrial water system and systems for monitoring and controlling the addition of such polymers including, for example, U.S. Pat. Nos. 5,171,450 and 6,153,110, the contents of which are hereby incorporated, in their entirety, by reference. Another approach to industrial water system controls is found in U.S. Pat. Nos. 6,510,368 and 6,068,012, the contents of which are hereby incorporated, in their entirety, by reference, which involves the direct measurement of one or more performance parameters including, for example, corrosion, scaling and fouling, on simulated detection surfaces.

Conventional cooling and boiler chemical treatment methods can reflect feedforward control based on feed water and system water demand including, for example, feeding a suitable treatment package into the industrial water system at a rate that takes into consideration the quality of the incoming feed water and/or condensate and the cycles of concentration under which the system is operating. These conventional treatment methods are designed to ensure that sufficient polymeric dispersant is maintained within the industrial water system in relation to the major contaminants, typically calcium, magnesium and iron, both to reduce or eliminate scale deposition on the wetted surfaces and to remove sufficient amounts of the contaminants through blowdown streams.

As noted above, one disadvantage of feedback control strategies is that they are reactive, requiring that a deviation must be detected in a controlled variable before the feedback controller takes action to adjust the manipulated variable. If the deviation is substantial and/or not arrested in a timely manner, corrosion, scaling and fouling can begin in the system before the feedback controller can bring the deviation under control. In practice, it has been observed that corrosion, scaling and fouling processes are interrelated and that once, started can exhibit a synergistic effect that increases the difficulty of reestablishing control within the industrial water system. Accordingly, it has been found that maintaining control over an industrial water system proactively is less expensive than trying to fix an out of control system.

### SUMMARY OF THE INVENTION

Disclosed are control systems that utilize measurements of various performance and system parameters, historical performance data and knowledge of the correlation(s) between the feed water, system water and the chemical treatment package(s) for improving industrial water system performance. The control systems utilize a combination of feedforward and feedback control methods with the overall response of the system to deviations in a monitored variable being determined by a ratio of the feedforward and feedback inputs. The control systems also incorporate industrial water system specific parameters to provide improved fail safe operation. The disclosed control system is capable of automatic operation over a wide range of process conditions and industrial water systems for balancing multiple performance objectives.

The various features which define the invention are reflected in the claims annexed to and forming a part of this disclosure. For a better understanding of the invention, its operating advantages and benefits obtained by its application, reference is made to the accompanying drawing and detailed description. The accompanying drawing is intended to show an example of an embodiment of the invention and should not be considered as unduly limiting the ways the invention can be practiced.

### BRIEF DESCRIPTION OF THE DRAWING

The FIGURE illustrates a flowchart reflecting an embodiment of the invention.

It should be noted that this FIGURE is intended to illustrate the general characteristics of the methods disclosed and to supplement the written description provided below. This drawing does not, however, precisely reflect the structural or logical arrangement of systems that could used to practice the disclosed methods or the performance characteristics of any given embodiment, and, accordingly, should not be interpreted as unduly defining or limiting the following claims.

### DETAILED DESCRIPTION OF THE INVENTION

Industrial water systems often present challenging operating environments that are contaminated and can include dirty water, high turbidity, microbiological contamination, varying chemistry, raw water, process leaks, size, complexity, seasonal changes, often while operating unattended or with reduced manpower for testing. Sensors utilized in the monitoring and control of such systems can fail to give accurate readings, require periodic calibration, cleaning and preventative maintenance. Feedback sensors can include those configured for monitoring, for example, fluorescence, ISE, colorimetric, conductivity and can be used inline or for offline testing of grab samples. Feedforward sensors can include those configured for monitoring, for example, water and/or chemical flows, mass balances and time.

As illustrated in the FIGURE, an embodiment of the control system 100 includes both a feedforward section FF, a feedback section FB and a control section CTRL that utilizes input from both the feedforward and feedback sections in determining the output control response. As illustrated in the FIGURE, the feedforward section can be configured for monitoring one or more variables 102 including, for example, input water flowrates, pH, conductivity, pump timing and pump output. The system incorporates one or more sensors or other devices arranged and configured to produce a signal corresponding to the monitored variable(s) 102. The signal(s) from the sensor(s) is then transmitted or otherwise relayed to the control section of the system, specifically the feedforward:feedback compensator 300.

As illustrated in the FIGURE, the feedback section can be configured for monitoring one or more variables 200 including, for example, polymer content, TDS, TSS, pH, conductivity, color and temperature. The system incorporates one or more sensors or other devices arranged and configured to produce a signal corresponding to the monitored variable(s) 202. The signal(s) from the sensor(s) is then transmitted or otherwise relayed to a comparator 204 that determines whether the sensed value of the target variable is above, at or below the setpoint. Depending on that determination, the feedback portion will generate a signal 206 reflecting a request to trim (reduce), boost (increase) or maintain (no change) one or more corresponding controllable variables. The trim/boost signal may correspond to a percentage of the controllable input and can be compared against predetermined limits to suppress overcorrection 208. After this comparison, a corresponding signal is forwarded or otherwise relayed to the controller section of the system, specifically the feedforward:feedback compensator 300.

Within the feedforward:feedback compensator 300 the inputs from the feedforward and feedback sections are combined according to a predetermined ratio to determine what, if any, adjustments should be made to one or more of the controllable variables. The system can be operated in a predominately feedforward mode when the FF:FB ratio is, for example, 80:20 or 70:30. The particular ratio may be determined through empirical testing and may be adjusted in response to the use of additional or alternative sensors and/or unusual changes in the values and/or historical performance of one or more sensors. Similarly, the system can be operated in a predominately feedback mode when the FF:FB ratio is, for example, 20:80 or 30:70. Such an arrangement could be useful in situations in which the feedforward variables are better controlled or if a particular feedback variable was deemed particularly critical.

The controller section CTRL also provides a Balance/Imbalance Check that can be configured for identifying sensor failures or other significant departures from the desired operating region. When, for example, a feedback variable indicated a need for a massive increase in the amount of the treatment package to be added to the makeup stream while the feedforward variable(s) does/do not reflect any dramatic changes in the incoming streams the control system would set an imbalance or out of balance alarm 304 reflecting the competing control inputs.

The controller is preferably configured for adaptive control wherein when an imbalance condition is detected, the system can engage one or more secondary sensors to confirm or rebut the primary sensor data. Alternatively, the system can revert to default control conditions that, based on the last trusted input data, will keep the system within specification and allow continued operation or a controlled maintenance shutdown. By operating in this manner, the system will be able to maintain satisfactory control even if one or more sensors fail.

When the feedforward and feedback inputs are in general agreement as to the necessary adjustments, the controller section will generate an adjustment control output signal 302 in order to modify the performance of the appropriate valve(s), pump(s) or other element(s) of the industrial water system in response to the detected deviation in the monitored variable(s). As noted above, the contribution to this adjustment control output signal from the feedforward and feedback sections of the system will be weighted in accord with the FF:FB ratio. This ratio may, however, be subject to adjustment in response to drift within one or more key variables.

The control system as illustrated in the FIGURE and as detailed herein can be used over a variety of different industrial water systems including, for example, recirculating systems, cooling tower systems and/or boiler systems.

Operating knowledge specific to the industrial water system in which the control system is deployed may be achieved through a combination of theoretical and/or empirical inputs that correlate water chemistry, treatment chemistry and water system performance. An example of a theoretical application would be a super-saturation index model which provides thermodynamic solubility limits for various hardness salts that are expected to be of interest in the specific industrial water system. An example of an empirical input would be test data collected for defining various operating zones or operating regions in which satisfactory corrosion and deposition inhibition has been demonstrated.

The operating regions reflect an underlying interdependency between parameters including, for example, pH, hardness, phosphate, alkalinity, and polymer concentration. Corrosion inhibition in a lower hardness regime, for example, typically utilizes increased pH and phosphate levels to achieve controlled precipitation of phosphate (i.e., cathodic protection) on cathodic areas of the wetted metal surface. For deposition inhibition, given the phosphate level being utilized for corrosion inhibition, a higher hardness regime will typically require a higher polymer level to be maintained in order to prevent precipitation in the circulating water.

As will be appreciated, the operating regions encompass both uncontrollable variables including, for example, feed water and system water chemistry variables, such as pH, hardness, alkalinity, phosphate, iron, aluminum, total dissolved solids (TDS), total suspended solids (TSS), bacteria loads, and combinations thereof and controllable variables including, for example, chemical treatment variables such as feed rates, treatment package composition, total and residual concentrations of corrosion inhibitor, deposition inhibitor and biocide, makeup water flow rates and blowdown water flow rates, and combinations thereof. The operating regions are defined by the known relationships between one or more of the controllable variables with their dependent or multiple-dependent uncontrollable variables for guiding control responses to variations in the target parameters. These predefined operating regions can be stored in or otherwise made available to the control elements of the system.

As will be appreciated by those in the art, a wide range of chemical treatment packages are available for addressing various conditions in a variety of industrial water systems. For cooling tower applications these conventional water treatment packages can include, for example, phosphonates, phosphates and phosphoric acid anhydrides, biocides, corrosion inhibitors including, for example, zinc and/or molybdenum salts, oxides and/or azoles, alkali metal(s) and alkaline earth hydroxide(s). For boiler water applications these conventional water treatment chemicals can include, for example, oxygen scavengers, e.g., sodium metabisulfite and hydrazine, phosphates and phosphoric acid anhydrides, chelants, e.g., EDTA, NTA or DTPA, and amines, e.g., ammonia, morpholine and cyclohexylamine. Other applications can include water treatment chemicals including, for example, amides, imidazolines, amidoamines, phosphonates, freezing point depressants, e.g., methyl alcohol, ethylene glycol and propylene glycol, biocides, polyethylene glycols, polypropylene glycols and fatty acids, coagulants, iron salts, surfactants and/or biocides. The particular treatment packages selected and the relative levels of the various chemical species depends on the treatment level desired and the particular conditions under which the treated industrial water system is being operated.

Polymers (including copolymers, terpolymers and/or quadpolymers) can be utilized in combination with conventional water treatment agents, and include, for example, phosphoric acids and their water soluble salts; phosphonic acids and their water soluble salts; amines; and oxygen scavengers. Phosphoric acids include, for example, orthophosphoric acid, polyphosphoric acids such as pyrophosphoric acid, tripolyphosphoric acid, metaphosphoric acids such as trimetaphosphoric acid, and tetrametaphosphoric acid. Examples of phosphonic acids include aminopolyphosphonic acids such as aminotrimethylene phosphonic acid, ethylene diamine tetramethylene phosphonic acid, methylene diphosplionic acid, hydroxy ethylidene-1,1-diphosphonic acid, and 2-phosphonobutane-1,2,4-tricarboxylic acid. Examples of amines include morpholine, cyclohexylamine, piperazine, ammonia, diethylaminoethanol, dimethyl isopropanolamine, methylamine, dimethylamine, methoxypropylamine, ethanolamine, diethanolamine, and hydroxylamine sulfite, bisulfite, carbohydrazide, citric acid, ascorbic acid and salt analogs. Examples of oxygen scavengers include hydroquinone, hydrazine, diethylhydroxylamine, hydroxyalkylhydroxylamine.

Polymers and copolymers may be added in combination with additional components, may be blended with additional chemical treatments, or may be added separately. Polymers and copolymers may be used in combination with conventional corrosion inhibitors for iron, steel, copper, copper alloys, or other metals, conventional scale and contamination inhibitors, metal ion sequestering agents, and other water treatment agents known in the art.

Treatment packages may also include additional chemical components including, for example, cathodic inhibitor(s), anodic inhibitor(s), anti-scalant(s), surfactant(s) and anti-foam agent(s), mineral acids, e.g., sulfuric acid, and/or alkaline materials, e.g., caustic soda. Other chemical components can be drawn from ferrous and non-ferrous corrosion inhibitors, scale control agents, dispersants for inorganic and organic foulants, oxidizing and non-oxidizing biocides, biodispersants as well as specialized contingency chemicals as deemed necessary to handle potential water chemistry upsets.

Feed water and/or system water variables can include, for example, makeup water flow rates, blowdown water flow rates, pH, hardness, alkalinity, phosphate content, iron content, aluminum content, TDS, TSS, bacteria loads and combinations thereof. Chemical treatment variables can include, for example, variables such as chemical feed rates, total and residual concentrations of corrosion inhibitor(s), deposition inhibitor content, biocide content, and combinations thereof.

By interrelating and coordinating a wider range of key variable feedforward and feedback inputs the feedforward/feedback control system according to the invention improves the overall control of the industrial water systems in which it is utilized. Controlling and monitoring changes in the input variables and applying system specific adaptive control responses provide fail-safe and fail-tolerant redundancy to a control scheme without necessitating the typical dual input similar sensor technology.

Typical fail-safe systems involve similar sensor or similar key variable inputs. When a single input system or even a dual input common redundancy system fails, whether as a result of sensor poisoning or mechanical failure, all control is lost. Incorporating dissimilar but key related feedforward and feedback variables in the control logic enables the feedforward/feedback system of the invention to be continually monitored and controlled rather than failing completely in the event a key variable fails or experiences an out of specification condition.

The system's feedforward and feedback monitoring and control are maintained after input report out of specification information. When such a condition is detected or suspected, the system can be configured for reporting the imbalance condition and/or setting an alarm in the event that one or more of the key input variables fails or develops an out of specification condition. These reports and/or alarms are used by maintenance to identify those sensors and/or components that need to be checked and repaired or replaces in order to restore the desired input signal.

While the present invention has been described with references to preferred embodiments, various changes or substitutions may be made on these embodiments by those ordinarily skilled in the art without departing from the scope of the present invention. Therefore, the scope of the present invention encompasses not only those embodiments described above, but all those that fall within the scope of the claims provided below.

We claim:

1. A control system for monitoring and controlling an industrial water system comprising:
a feedforward section configured for generating a first input signal corresponding to a first monitored variable;
a feedback section configured for generating a second input signal corresponding to a second monitored variable; and
a control section configured for generating an output signal wherein the output signal represents a weighted response to the first and second input signals.
